(19) United States
(12) Patent Application Publication
(10) Pub. No.: US 2010/0052544 A1
(43) Pub. Date: Mar. 4, 2010

(54) PWM CONTROLLING CIRCUIT, APPARATUS OF CONTROLLING BACKLIGHT COMPRISING THE SAME, AND APPARATUS OF DRIVING BACKLIGHT COMPRISING THE APPARATUS OF CONTROLLING BACKLIGHT

(75) Inventors: Ki Jeom Park, Seoul (KR); Soo Yeub Yoo, Chungcheongbuk-do (KR)

Correspondence Address: Muncy, Geissler, Olds & Lowe, PLLC, P.O. BOX 1364, FAIRFAX, VA, 22038-1364, US

(73) Assignee: Luminous LED Co., Ltd., Ansan-city, Kyunggi-do (KR)

(21) Appl. No.: 12/515,748

(22) PCT Filed: Nov. 21, 2007
(86) PCT No.: PCT/KR2007/005866

§ 371 Date: May 21, 2009

(30) Foreign Application Priority Data
Nov. 21, 2006 (KR) 10-2006-0115484

(51) Int. Cl. H05B 37/02; H03K 3/017

(52) U.S. Cl. 315/149; 327/175; 315/287

(57) ABSTRACT

A pulse width modulation (PWM) control circuit is disclosed. The PWM control circuit includes an adder summing up an input signal and a conversion signal to generate a summation signal, a quantizer quantizing the summation signal generated by the adder to output a quantization signal, a subtractor subtracting the summation signal from the quantization signal to output a subtraction signal, a filter filtering the subtraction signal to have a predetermined bandwidth to limit the frequency and converting the subtraction signal to provide the adder with the conversion signal, and a synchronization gate controlling the quantization signal by the gate signal inputted therein to output a PWM control signal having a same duty ratio as the quantization signal and a portion of which is off, and temporarily stopping an operation of the adder, the quantizer, the subtractor and the filter.

### TECHNICAL FIELD

The present invention relates to a pulse width modulation (PWM) control circuit, a backlight control apparatus having the PWM control circuit, and a backlight driving apparatus having the backlight control apparatus. More particularly, the present invention relates to a PWM control circuit capable of generating PMW control signal having enhanced resolution without increasing clock frequency and of diluting quantization noise by dispersing, a backlight control apparatus having the PWM control circuit, and a backlight driving apparatus having the backlight control apparatus.

### BACKGROUND ART

A fluorescent lamp, for example, a cold cathode fluorescent lamp (CCFL) type is mostly used for a backlight of a liquid crystal display (LCD). However, an environment-friendly, mercury-free product is required. Thus, instead of the CCFL, a light emission diode (LED) is promising as light source.

In addition to environmental advantage, the LED backlight is more effective in energy saving than existing light sources, and may be semipermanently used, so that the LED backlight is becoming popular as the light source of the next generation. As a result, studies are actively carried out in the LED backlight with the improvement in the problems of luminance and cost.

In order to be used for the backlight, white-colored light generated by a white-colored LED is used, or the white-colored light may be obtained from the optical combination of the three primary colors of red, green and blue by using a red-colored LED, a green-colored LED and a blue-colored LED. Particularly, the method of using the three primary colored LEDs is actively reviewed to be used for the television because it is easy to maintain the balance of the colors.

Such a backlight using a red-colored LED, a green-colored LED and a blue-colored LED as the light sources should optically combine red, green and blue-colored lights at a specific proportion to constantly generate the white-colored light having the fixed chromaticity. Thus, the intensity of the radiation of each colored light is detected by the photosensor of red, green and blue colors, and the above-mentioned three colors are combined at a specific proportion by feedback control, so that the white-colored light having the fixed chromaticity is constantly adjusted.

Meanwhile, lots of methods of driving LED by using the PWM signal have been presented. Such methods of operating PWM are limited in enhancing the resolution. In other words, the PWM signal requires the system clock frequency of an exponential function. For example, in order to obtain 12-bits resolution with an output PWM frequency of about 56 KHZ, the clock frequency inputted to a counter is required to be more than about 229 MHz. In order to obtain 16-bits resolution for higher resolution power, the clock frequency of about 3.67 GHz is required. Such a clock frequency is not suitable for a semiconductor circuit. Also, the frequency of about 229 MHz is too high for a common integrated circuit (IC).

### DISCLOSURE

### Technical Problem

The present invention provides a PWM control circuit capable of generating PMW control signal having enhanced resolution without increasing clock frequency and of diluting quantization noise by dispersing.

The present invention also provides a backlight control apparatus for LED, which is capable of controlling uniformly the brightness of a whole screen and precisely controlling the luminance of each portion of the whole screen, and a backlight driving apparatus having the backlight control apparatus.

### Technical Solution

A PWM control circuit in accordance with an aspect of the present invention includes an adder, a quantizer, a subtractor, a filter and a synchronization gate. The adder sums up an input signal and a conversion signal to generate a summation signal. The quantizer quantizes the summation signal generated by the adder to output a quantization signal. The subtractor subtracts the summation signal from the quantization signal to output a subtraction signal. The filter filters the subtraction signal to have a predetermined bandwidth to limit the frequency, and converts the subtraction signal to provide the adder with a conversion signal. The synchronization gate controls the quantization signal by the gate signal inputted therein to output a PWM control signal having a same duty ratio as the quantization signal, and a portion of which is off, and temporarily stops an operation of the adder, the quantizer, the subtractor and the filter.

A backlight control apparatus in accordance with another aspect of the present invention includes a serial-parallel conversion shift register, a plurality of registers and the aforesaid PWM control circuits. The serial-parallel conversion shift register outputs parallel data by shifting serial data according to a clock signal. The registers store the parallel data outputted from the serial-parallel conversion shift register. The PWM control circuits are electrically connected to the registers.

A backlight driving apparatus in accordance with still another aspect of the present invention includes a backlight unit, a variable voltage source unit, a steady current driving unit, a terminal voltage detecting unit and a control unit. The backlight unit includes a plurality of light emitting regions electrically separated from each other. The variable voltage source unit receives a power source and a voltage control signal to independently output controlled voltages to the light emitting regions. The steady current driving unit includes a plurality of steady current circuits, each of which receives a PWM control signal to independently control a pulse width and a duty of current applied to the light emitting regions. The terminal voltage detecting unit detects terminal voltages of the steady current circuits. The control unit includes the aforesaid backlight control apparatus, outputs the voltage control signal to the variable voltage source unit and the PWM control signal to the steady current driving unit, based on terminal voltages detected by the terminal voltage detecting unit.

### ADVANTAGEOUS EFFECTS

The present invention provides the following advantageous effects.

First, according to the PWM control circuit of the present invention, the PWM signal having a high resolution may be generated without increasing a clock frequency. Therefore, a digital IC may be generated with a chip of relatively lower price. Also, power consumption and heating of the chip may be reduced, electromagnetic effects such as high frequency failure may be reduced, and luminance and chromaticity of the LED backlight may be precisely controlled. Additionally, the quantization noise may be diluted by dispersing.

Second, according to the backlight control apparatus and the backlight driving apparatus according to the present invention, luminance of entire LED backlight may be uniformly controlled by simultaneously controlling duty ratio of the PWM pulse and on/off of the PWM pulse, and luminance and chromaticity of each portion of the LED backlight may be precisely controlled if necessary.

Third, the backlight control apparatus and the backlight driving apparatus according to the present invention may be applied to a color filter-less (CFL) LCD not having color filters and, instead, sequentially turning on/off a red-colored LED, a green-colored LED and a blue-colored LED equipped in each pixel by synchronizing them with an LCD display.

Fourth, the backlight control apparatus and the backlight driving apparatus according to the present invention may be applied to a driving method which precisely controls the LEDs of the whole system according to the duration of an image displayed on an LCD in order to prevent motion blurring effects.

### DESCRIPTION OF DRAWINGS

The above and other advantages of the present invention will become more apparent by describing in detail exemplary embodiments thereof with reference to the accompanying drawings, in which:

FIG. 1 is a circuit diagram showing a pixel of a TFT-LCD capable of employing a backlight that is driven according to an exemplary embodiment of the present invention;

FIG. 2 is a perspective view roughly showing an LCD capable of employing a backlight that is driven according to an exemplary embodiment of the present invention;

FIG. 3 is an exemplary embodiment of a backlight control apparatus according to the present invention;

FIG. 4 is a block diagram showing an exemplary embodiment of a PWM control circuit according to the present invention;

FIG. 5 is a graph showing quantization noises generated by a conventional PWM generating circuit;

FIG. 6 is a graph showing quantization noises generated by an exemplary embodiment of a PWM control circuit according to the present invention;

FIG. 7 is a block diagram showing an exemplary embodiment of a backlight driving apparatus according to the present invention; and

FIG. 8 is a block diagram showing another exemplary embodiment of a backlight driving apparatus according to the present invention.

### MODE FOR INVENTION

Hereinafter, the present invention will be described in detail with reference to the accompanying drawings.

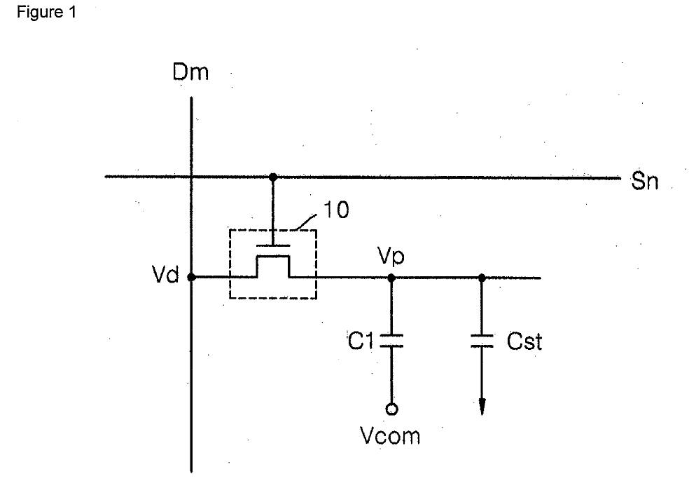

FIG. 1 is a circuit diagram showing a pixel of a TFT-LCD capable of employing a backlight that is driven according to an exemplary embodiment of the present invention.

Referring to FIG. 1, each pixel of the LCD includes a thin film transistor (TFT) 10, a liquid crystal capacitor C1 and a storage capacitor Cst. A source electrode of the TFT is electrically connected to a data line Dm, and a gate electrode of the TFT is electrically connected to a scan line Sn. The liquid crystal capacitor C1 is electrically connected between a drain electrode of the TFT and a common electrode (not shown). The storage capacitor Cst is electrically connected to the drain electrode.

The TFT 10 provides a pixel electrode (not shown) with a data voltage Vd provided by the data line Dm, in response to a scan signal provided by the scan line Sn. When an electric field corresponding to a voltage difference between the data voltage (or pixel voltage Vp) and the common voltage Vcom applied to a common electrode (not shown) is applied to liquid crystal, which is equivalently shown as the liquid crystal capacitor C1 in FIG. 1. The liquid crystal controls light transmittance thereof in accordance with the electric field. The storage capacitor Cst maintains the pixel voltage applied to the liquid crystal capacitor C1 until a next pixel voltage is applied to the liquid crystal capacitor C1, so that light can be transmitted for a predetermined duration of time.

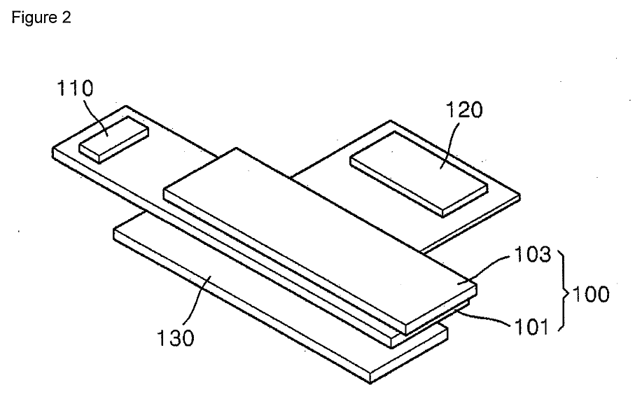

FIG. 2 is a perspective view roughly showing an LCD capable of employing a backlight that is driven according to an exemplary embodiment of the present invention.

Referring to FIG. 2, the LCD includes a liquid crystal panel 100. The liquid crystal panel 100 includes a lower substrate 101, an upper substrate 103 and liquid crystal (not shown) disposed between the lower substrate 101 and the upper substrate 103. The lower substrate 101 has a TFT array (not shown) in which a plurality of scan lines, a plurality of data lines and a plurality of common lines are connected to a thin film transistor for switching. The upper substrate 103 includes a common electrode (not shown) providing the common line with the common voltage Vcom.

The LCD further includes a scan line driving circuit 110, a data line driving circuit 120 and a backlight 130. The scan line driving circuit 110 provides the gate lines with scan signals. The data line driving circuit 120 provides the data lines with data signals. The backlight 130 provides the liquid crystal panel 100 with light.

The backlight 130 includes a white-colored light emitting diode (LED) generating white light, or a red-colored LED, a green-colored LED and a blue-colored LED. The backlight 130 may further include a light guide plate.

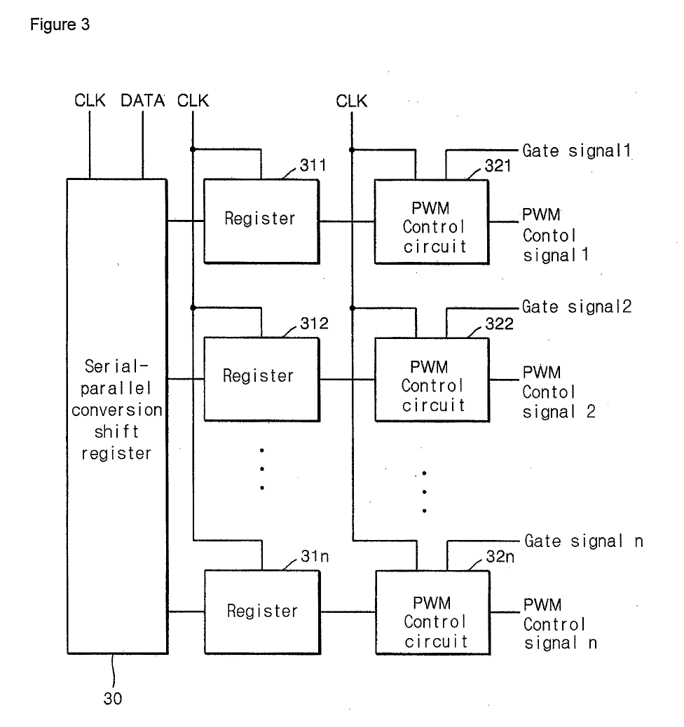

FIG. 3 is an exemplary embodiment of a backlight control apparatus according to the present invention.

Referring to FIG. 3, an exemplary embodiment of a backlight control apparatus according to the present invention includes a serial-parallel conversion shift register 30, registers 311, 312, . . . , 31n, and PWM control circuits 321, 322, . . . , 32n.

The serial-parallel conversion shift register 30 outputs parallel data by shifting serial data DATA according to a clock signal CLK. The serial data DATA may be formed by a microcomputer, and are data for a duty ratio of each of PWM signals.

The registers 311, 312, . . . , 31n store the parallel data outputted from the serial-parallel conversion shift register 30. The stored data are maintained until new data are inputted.

The PWM control circuits 321, 322, . . . , 32n generate PWM control signals having high resolution without increasing clock frequency, and dilute quantization noises of the PWM control signals by dispersing.

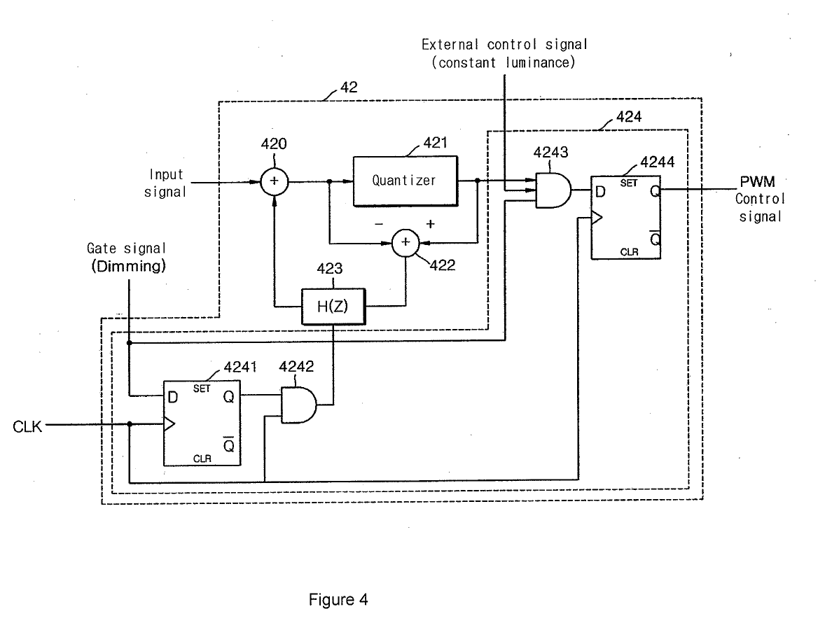

FIG. 4 is a block diagram showing an exemplary embodiment of a PWM control circuit according to the present invention.

Referring to FIG. 4, an exemplary embodiment of a PWM control circuit according to the present invention includes an adder 420, a quantizer 421, a subtractor 422, a filter 423 and a synchronization gate 424.

The adder 420 sums up the input signals stored in the registers 311, 312, . . . , 31n and the conversion signals from the filter 423 to output a summation signal. The input signal may be a required duty ratio of the PWM signal.

The quantizer 421 quantizes the summation signal of the adder 420 to output quantization signal. The quantization signal may be the PWM signal.

The subtractor 422 subtracts the summation signal outputted from the adder 420 from the quantization signal outputted from the quantizer 421 to output a subtraction signal.

The filter 423 filters the subtraction signal to have a specific bandwidth to limit the frequency, and converts the subtraction signal to provides the adder 420 with a conversion signal. The filter 423 may be a low pass filter (LPF) reducing the quantization noise of the subtraction signal.

The filter 423 may be expressed by various transfer functions, and those skilled in the art may property choose one. For example, those skilled in the art may design the filter by using a fourth or fifth order transfer function, considering the required frequency. Since an objective of the present invention is generating the PWM signal for exactly applying direct current to LED, an intensity of the direction current should arrive at a required value as soon as possible. Therefore, the LPF may be formed by a system having a proper time constant for LCD operation.

The synchronization gate 424 controls the quantization signal by the gate signal inputted therein to output the PWM control signal having the same duty ratio as the quantization signal, and a portion of which is off, and temporarily stops an operation of the adder 420, the quantizer 421, the subtractor 422 and the filter 423 by the gate signal.

The plurality of PWM control signals outputted from the synchronization gate 424 may be applied to each of the light emitting regions in FIG. 3, to each of the red-colored LED, the green-colored LED and the blue-colored LED in each of the light emitting regions, or to each of the red-colored LED, the green-colored LED and the blue-colored LED in one pixel.

The synchronization gate 424 includes a first D-flipflop 4241, a second D-flipflop 4244, a first AND-gate 4242 and a second AND-gate 4243.

The first D-flipflop 4241 includes a data input terminal D, a clock input terminal and an output terminal Q. The first D-flipflop 4241 receives the gate signal and the clock signal through the data input terminal D and the clock input terminal, respectively, and outputs the gate signal synchronized to the clock signal through the output terminal Q.

The first AND-gate 4242 performs an AND-operation of the synchronized gate signal and the clock signal to output a stop signal to the filter 423.

The second AND-gate 4243 performs an AND-operation of the quantization signal and the gate signal and outputs the result. Alternatively, the second AND-gate 4243 may perform an AND-operation of the quantization signal, the gate signal and an external control signal and output the result.

When the PWM control signal having the same duty ratio as the quantization signal, and a portion of which is off, is outputted, the external control signal may be adjusted to give constant luminance.

The second D-flipflop 4244 includes a data input terminal D, a clock input terminal and an output terminal Q. The second D-flipflop 4244 receives the output signal of the second AND-gate 4243 and the clock signal through the data input terminal D and the clock input terminal, respectively, and outputs the PWM control signal through the output terminal Q.

Hereinafter, the operation of an exemplary embodiment of the PWM control circuit according to the present invention will be explained referring to FIGS. 3 and 4.

In a system having an 8-bits resolution, a 16-bits signal, for example an input signal for 51% duty ratio, is applied to the adder 420 through the registers 311, 312, . . . , 31n. The quantizer 421 generates the PWM signal in accordance with the clock pulse. However, the quantizer 421 cannot generate an exact 51% duty ratio due to the 8-bits resolution, but generates, for example, 50.8% duty ratio. Then, the subtractor 422 subtracts the summation signal from the quantization signal to output 0.2% subtraction signal to the filter 424, and the filter 424 which may be expressed by a predetermined transfer function converts the subtraction signal to 0.2% conversion signal. Then, the adder 420 sums up the 51% input signal and the 0.2% conversion signal to output 51.2% summation signal, and the quantizer 421 outputs 51.2% quantization signal.

According to the PWM signal outputted from the quantizer 421, each has 8-bits resolution, and thus the exact 51% duty ratio cannot be obtained. However, by combining two PWM pulses, one with 50.8% duty ratio and the other with 51.2% duty ratio, the 51% duty ratio may be attained. Therefore, 16-bits resolution can be obtained.

This kind of enhancement of performance may be further increased by employing an oversampling. The synchronization gate 424 controls the quantization signal by the gate signal inputted therein to output the PWM control signal having the same duty ratio as the quantization signal, and a portion of which is off. The synchronization gate 424 temporarily stops an operation of the adder 420, the quantizer 421, the subtractor 422 and the filter 423. The PWM control signal has characteristics of having same duty ratio as the PWM control signal, and some cycles are off at a cycle basis. By maintaining the duty ratio constant, the gate signal controlling on-off of the PWM pulse may be easily designed.

An input making an output of this apparatus to be zero is inputted through other input terminal. The input turns off the output of the system to synchronize the signal of the LED. An inner filter of the system recognizes that the output is zero and controls PWM such that it increases output. That is, the amount of LED compulsively turned off is compensated. This means that even when an output of the entire system is changed to have a pulse shape by an external synchronization signal, the amount of light that is emitted is not changed. In other words, even though the system is operated such that the output is changed to have a pulse shape, the amount of emitted light remains unchanged.

The filter 423 is a digital filter adding the difference between the output corresponding to the PWM signal that is quantized by the quantizer 421 and the inputted digital value to a next signal in order to reduce noises induced by quantizing. The PWM circuit not having such a digital filter can reduce the noise only through a high resolution PWM.

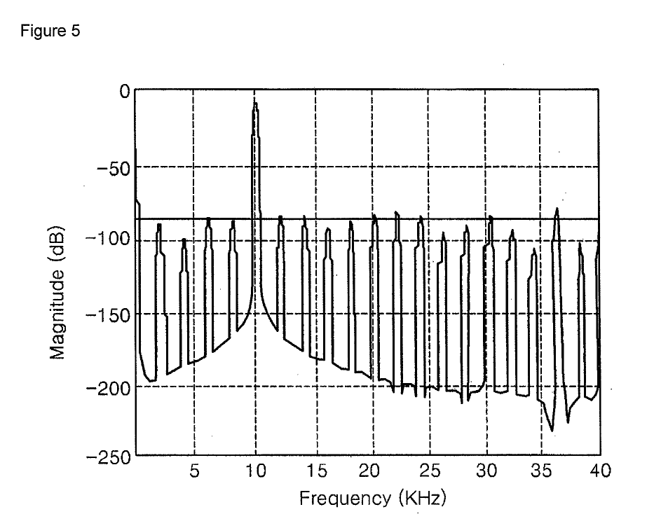

FIG. 5 is a graph showing quantization noises generated by a conventional PWM generating circuit.

In the conventional 8- to 10-bits system, the output of the PWM contains noises due to a quantization, as shown in FIG. 5. This kind of quantization noise induces fluctuation in light output, which is combined with the LCD scan period to result in various side effects. Especially, the quantization noise becomes a cause of spurious radiation.

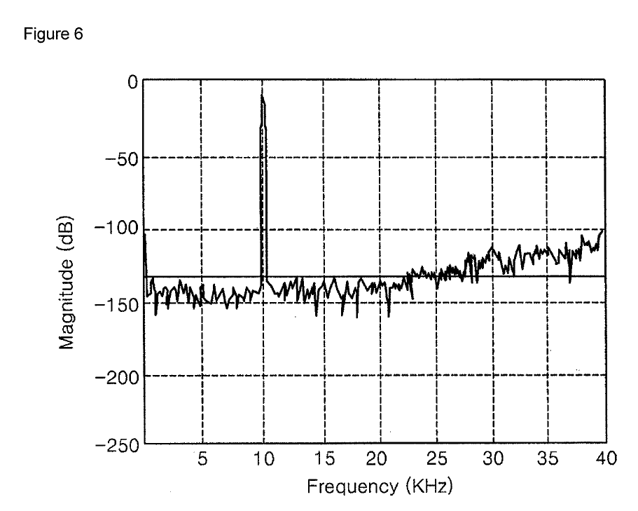

FIG. 6 is a graph showing quantization noises generated by an exemplary embodiment of a PWM control circuit according to the present invention.

In FIG. 6, PWM is a graph of a signal not only for a direct current but also for about 10 KHz PWM signal. Referring to FIG. 6, when the PWM control signal according to an exemplary embodiment of the present invention is employed, a high quality PWM signal without noises may be generated.

The quantization noise corresponds to a difference between the input and the output. Therefore, FIG. 6 shows that the output is formed to have more than 16-bits of digital value as compared to the input. That is, FIG. 6 shows that the circuit corresponds to equal to or more than 16-bits, with the noise being about −100 dB.

Strictly speaking, the dilution of the quantization noise is not a removal of a noise but a dilution of the noise into other frequencies. Referring to FIG. 5, the noise level is almost down to −200 dB. However, such noise level has no meaning. Rather, the noise at about −80 dB has greater influence on the system.

Therefore, the clock should be raised ultimately, but the quantization noise may be reduced by adjusting an oversampling ratio. For example, when the bits are reduced to have the same bits and the oversampling ratio is raised in a system reproducing a PWM signal of about 10 KHz, a relationship between the clock and the maximum value of the quantization noise and a proper oversampling ratio may be obtained as Table 1.

TABLE 1

| Operation | Oversampling | PWM | Maximum value of |
|---|---|---|---|
| Frequency | Ratio | Resolution | quantization noise |
| (MHz) | (~times) | (bits) | (dB) |
| 49.152 | 2 | 9 | −64.98 |
| | 4 | 8 | −96.3 |
| | 8 | 7 | −79.27 |
| | 16 | 6 | −63.33 |
| 98.304 | 2 | 10 | −68.13 |
| | 4 | 9 | −104.35 |
| | 8 | 8 | −108.89 |
| | 16 | 7 | −81.06 |
| 196.608 | 2 | 11 | −70.96 |
| | 4 | 10 | −110.87 |
| | 8 | 9 | −120.07 |
| | 16 | 8 | −116.7 |
| 393.216 | 2 | 12 | −73.4 |
| | 4 | 11 | −116.43 |
| | 8 | 10 | −132.05 |
| | 16 | 9 | −129.2 |

That is, a proper relationship between oversampling and the PWM can make the circuit operate smoothly. Such a reduction of noise may be obtained and enhanced by the oversampling of the output. For example, when the 8-bits PWM signal and the 4-times oversampling period are embodied in case that 48 KHz PWM is generated by 49.152 MHz clock, the quantization noise is optimized to −96 dB. This calculated value is enough for high resolution data, for example, 16-bits data.

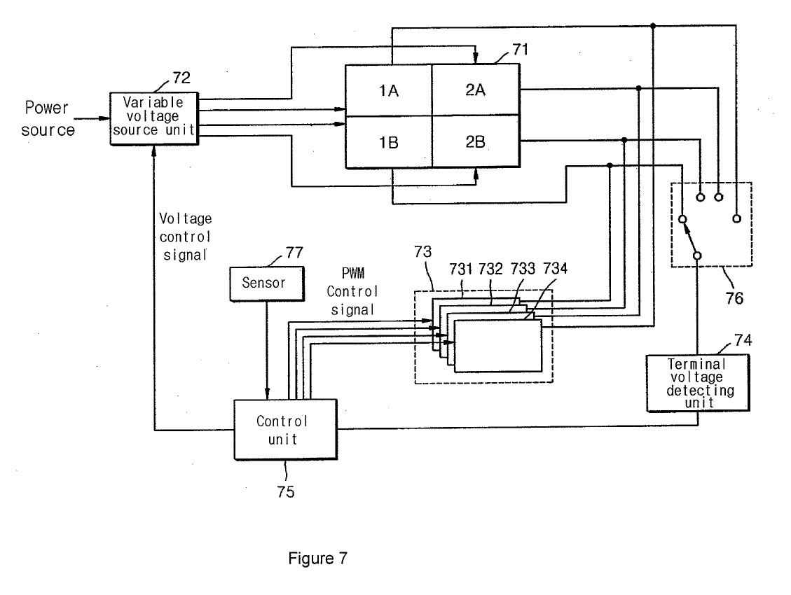

FIG. 7 is a block diagram showing an exemplary embodiment of a backlight driving apparatus according to the present invention.

Referring to FIG. 7, an exemplary embodiment of a backlight driving apparatus according to the present invention includes a backlight unit 71, a variable voltage source unit 72, a steady current driving unit 73, a terminal voltage detecting unit 74, a control unit 75, a detection channel selecting unit 76 and a sensor 77.

The backlight unit 71 includes a plurality of light emitting regions electrically separated from each other. In FIG. 7, the backlight unit 71 has, for example, four light emitting regions 1A, 1B, 2A, 2B.

Each of the light emitting regions 1A, 1B, 2A, 2B includes a white light emitting diode as a backlight. Though not shown in FIG. 7, the light emitting diodes may be connected with each other in series.

The variable voltage source unit 72 receives an input power from an external power source and a voltage control signal from the control unit 75, and independently outputs a controlled voltage to the light emitting regions 1A, 1B, 2A, 2B.

The variable voltage source unit 72 is a power source circuit providing the LEDs of the light emitting regions 1A, 1B, 2A, 2B with current. In order to connect the LEDs in series and turn them on, a high voltage may be required. The variable voltage source unit 72 is a power source circuit precisely controlling the required voltage. Since the LED is a semiconductor device which is sensitive to a temperature variation, the variable voltage source unit 72 should compensate the voltage due to the characteristics change of the LED.

The magnitude of the voltage applied to the LEDs of the light emitting regions 1A, 1B, 2A, 2B is determined by a signal from the control unit 75. In detail, the voltage-current characteristics of LEDs are changed according to the temperature. Therefore, the voltage should be controlled to optimize power consumption. The variable voltage source unit 72 controls the voltage. The output voltage is used by the LEDs and the steady current driving unit 73. When the output voltage increases, a heat loss by the steady current driving unit 73 increases and, thus, temperature thereof increases. Therefore, the control unit 75 controls the voltage applied to the steady current driving unit 73, such that a minimum voltage is maintained, by detecting the voltage of the steady current driving unit 73.

The steady current driving unit 73 includes a plurality of steady current circuits 731, 732, 733, 734, each of which receives the PWM control signal from the control unit 75 to independently control the pulse width and duty of the current applied to the light emitting regions 1A, 1B, 2A, 2B.

The detection channel selecting unit 76 selects steady current circuits which are turned on from the steady current circuits 731, 732, 733, 734, and the terminal voltage detecting unit 74 detects the terminal voltage of the selected steady current circuits. The terminal voltage detecting unit 74 may be an analog-to-digital converter (ADC).

The voltage of the LED and the terminal voltages of the steady current circuits 731, 732, 733, 734 determine the voltage outputted from the variable voltage source unit 72. The voltage of the LED is determined by itself. Therefore, according to the present invention, a voltage required by the variable voltage source unit 72 is calculated by using the terminal voltages of the steady current circuits 731, 732, 733, 734.

The sensor 77 senses a luminance, temperature and/or chromaticity of each light emitting region 1A, 1B, 2A, 2B or of each LED or LED array contained in each region. Then the sensor provides the control unit 75 with the information of the luminance, temperature and/or chromaticity.

The control unit 75 includes an exemplary embodiment of an LED backlight control apparatus according to the present invention. The control unit 75 provides the variable voltage source unit 72 with a voltage control signal, and the steady current driving unit 73 with the PWM control signal by using the terminal voltage information of the steady current circuits 731, 732, 733, 734 detected by terminal voltage detecting unit 74 and the information of the luminance, temperature and/or chromaticity provided by the sensor 77.

Therefore, the luminance and color characteristics of each of the light emitting regions 1A, 1B, 2A, 2B may be precisely controlled, so that the entire luminance and color characteristics of the backlight 71 may be controlled uniformly.

The control unit 75 performs a feedback control for independently controlling LED currents applied to the each region using the information of luminance and temperature from all sensors in order to maintain the luminance of each portion of the backlight as set by a user.

Furthermore, the control unit 75 calculates the value of controlled source voltage in order to apply an optimized voltage to a terminal of a transistor by detecting the terminal voltage of the transistor, while the transistor is turned on to allow a current to flow through a backlight driving circuit. The control unit 75 provides the variable voltage source unit 72 with the resultant voltage control signal, in order to reduce power consumption of the entire backlight driving circuit.

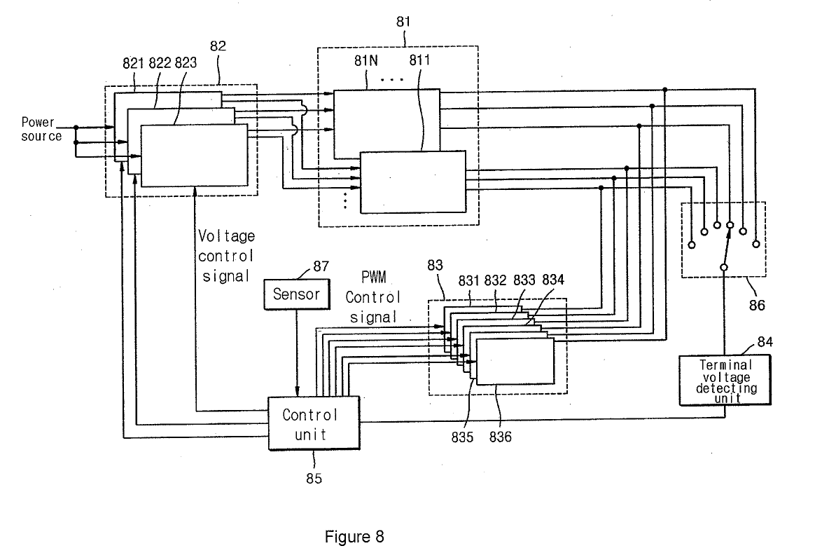

FIG. 8 is a block diagram showing another exemplary embodiment of a backlight driving apparatus according to the present invention. In FIG. 8, the light emitting regions 811, . . . , 81N are illustrated as overlapping with each other. However, actually, the light emitting regions 811, . . . , 81N are represented as configured as in FIG. 7.

Referring to FIG. 8, each of the light emitting regions 811, . . . , 81N may include a red-colored LED, a green-colored LED and a blue-colored LED.

The variable voltage source unit 82 includes a variable voltage source 821 for the red-colored LED, a variable voltage source 822 for the green-colored LED and a variable voltage source 823 for the blue-colored LED, and each of steady current driving units 831, 832, 833, 834, 835, 836 is electrically connected to the LEDs of the light emitting regions 811, . . . , 81N.

The control unit 85 includes an exemplary embodiment of an LED backlight controller according to the present invention, and receives the information of the luminance and temperature from each sensor 87 and the input signal of a user to determine the luminance of red-, green- and blue-colored LEDs of each of the light emitting regions 811, . . . , 81N.

This invention has been described with reference to the exemplary embodiments. It is evident, however, that many alternative modifications and variations will be apparent to those skilled in the art in light of the foregoing description. Accordingly, the present invention embraces all such alternative modifications and variations as falling within the spirit and scope of the appended claims.

### INDUSTRIAL APPLICABILITY

The present invention relates to a PWM control circuit, a backlight control apparatus having the PWM control circuit, and a backlight driving apparatus having the backlight control apparatus. More particularly, the present invention relates to a PWM control circuit capable of generating PMW control signal having enhanced resolution without increasing clock frequency and of diluting quantization noise by dispersing, a backlight control apparatus having the PWM control circuit, and a backlight driving apparatus having the backlight control apparatus.

1. A pulse width modulation (PWM) control circuit comprising:
an adder summing up an input signal and a conversion signal to generate a summation signal;
a quantizer quantizing the summation signal generated by the adder to output a quantization signal;
a subtractor subtracting the summation signal from the quantization signal to output a subtraction signal;
a filter filtering the subtraction signal to have a predetermined bandwidth to limit the frequency, and converting the subtraction signal to provide the adder with the conversion signal; and
a synchronization gate controlling the quantization signal by the gate signal inputted therein to output a PWM control signal having a same duty ratio as the quantization signal and a portion of which is off, and temporarily stopping an operation of the adder, the quantizer, the subtractor and the filter.

2. The PWM control circuit of claim 1, wherein the quantization signal is a PWM signal.

3. The PWM control circuit of claim 1, wherein the filter is a low pass filter (LPF) reducing the quantization noise of the subtraction signal.

4. The PWM control circuit of claim 1, wherein the synchronization gate comprises:
a first D-flipflop comprising a data input terminal receiving the gate signal, a clock input terminal receiving a clock signal and an output terminal outputting a gate signal synchronized to the clock signal;
a first AND-gate performing an AND-operation of the synchronized gate signal and the clock signal to output a stop signal to the filter;
a second AND-gate performing an AND-operation of the quantization signal and the gate signal to output a result thereof; and
a second D-flipflop comprising a data input terminal receiving the result of the second AND-gate, a clock input terminal receiving a clock signal and an output terminal outputting a PWM control signal.

5. The PWM control circuit of claim 4, wherein the second AND-gate performs an AND-operation of the quantization signal, the gate signal and an external control signal to output a result thereof, and
a luminance is adjusted to be uniform by the external signal when the PWM control signal having the same duty ratio as the quantization signal, and a portion of which is off, is outputted.

6. A backlight control apparatus comprising:
a serial-parallel conversion shift register outputting parallel data by shifting serial data according to a clock signal;
a plurality of registers storing the parallel data outputted from the serial-parallel conversion shift register; and
PWM control circuits of any one of claims 1 through 5, which are electrically connected to the registers.

7. A backlight driving apparatus comprising:
a backlight unit comprising a plurality of light emitting regions electrically separated from each other;
a variable voltage source unit receiving a power source and a voltage control signal and independently outputting controlled voltages to the light emitting regions;
a steady current driving unit comprising a plurality of steady current circuits, each of which receives a PWM control signal to independently control a pulse width and a duty of current applied to the light emitting regions;
a terminal voltage detecting unit detecting terminal voltages of the steady current circuits; and
a control unit comprising the backlight control apparatus of claim 6, outputting the voltage control signal to the variable voltage source unit and the PWM control signal to the steady current driving unit, based on terminal voltages detected by the terminal voltage detecting unit.

8. The backlight driving apparatus of claim 7, further comprising a detection channel selecting unit selecting one of the steady current circuits, which is turned on.

9. The backlight driving apparatus of claim 7, further comprising a sensor sensing luminance, temperature or chromaticity of the light emitting regions and provides the control unit with information of the luminance, temperature or chromaticity.
